(19) United States
(12) Patent Application Publication
(10) Pub. No.: US 2025/0127015 A1
(43) Pub. Date: Apr. 17, 2025

(54) DISPLAY DEVICE

(71) Applicant: Sharp Display Technology Corporation, Kameyama City, Mie (JP)

(72) Inventor: Toshihiro KANEKO, Kameyama City, Mie (JP)

(21) Appl. No.: 18/686,488

(22) PCT Filed: Oct. 25, 2021
(86) PCT No.: PCT/JP2021/039355

§ 371 Date: Feb. 26, 2024

(51) Int. Cl. H10K 59/80; H10K 59/131

(52) U.S. Cl. CPC H10K 59/873; H10K 59/131

(57) ABSTRACT

Each lead wiring line includes a first wiring line provided on a display region side and formed of the same material and in the same layer as a second metal layer, a second wiring line provided on a bending portion side and formed of the same material and in the same layer as the second metal layer, and a third wiring line provided between the first wiring line and the second wiring line, formed of the same material and in the same layer as the first metal layer and electrically connected to each of the first wiring line and the second wiring line via a first contact hole and a second contact hole formed in an inorganic insulating film.

### TECHNICAL FIELD

The disclosure relates to a display device.

### BACKGROUND ART

In recent years, as a display device replacing a liquid crystal display device, a self-luminous organic electroluminescence (hereinafter also referred to as “EL”) display device using an organic EL element has attracted attention. For this organic EL display device, a flexible organic EL display device in which an organic EL element or the like is formed on a resin substrate having flexibility has been proposed.

For example, PTL 1 discloses a display device including a first inorganic insulating layer provided on a substrate in a display region and a mounting region, a wiring line provided on the first inorganic insulating layer and extending over the display region, the mounting region, and a bending region, and a second inorganic insulating layer provided on the wiring line, in which the second inorganic insulating layer extends to a region overlapping at least the first inorganic insulating layer.

### CITATION LIST

### Patent Literature

PTL 1: JP 2019-211676 A

### SUMMARY

### Technical Problem

Incidentally, in an organic EL display device, a frame region is provided around a display region for performing image display, a terminal portion is provided at an end portion of the frame region, and a wiring line extending to the display region is provided so as to extend to the terminal portion. Here, although an organic resin film is provided on the wiring line to cover the wiring line, the organic resin film is often provided to be divided into a display region and a frame region in order to prevent moisture from infiltrating into organic EL elements of respective subpixels in the display region through the organic resin film. However, moisture contained in the organic resin film in the frame region moves to the display region side along the surface of the wiring line, and thus the moisture may infiltrate into the organic EL elements of the respective subpixels, resulting in a concern that a light-emitting layer constituting the organic EL element may be deteriorated. Thus, there is room for improvement.

The disclosure has been made in view of such circumstances, and an object thereof is to suppress infiltration of moisture into a display region.

### Solution to Problem

In order to achieve the above-described object, a display device according to the disclosure includes a resin substrate, a thin film transistor layer provided on the resin substrate and in which a first metal layer, an inorganic insulating film, a second metal layer, and an organic resin film are layered in order, a light-emitting element layer provided on the thin film transistor layer and in which a plurality of light-emitting elements are arrayed corresponding to a plurality of subpixels constituting a display region, and a sealing film provided on the light-emitting element layer to cover the light-emitting element layer and in which a first inorganic sealing film, an organic sealing film, and a second inorganic sealing film are layered in order, in which a frame region is provided around the display region, a terminal portion is provided at an end portion of the frame region, a bending portion is provided between the display region and the terminal portion, the bending portion extending in one direction, a plurality of lead wiring lines are provided between the display region and the bending portion in the frame region, the plurality of lead wiring lines extending in parallel with each other in a direction intersecting a direction in which the bending portion extends, and each of the lead wiring lines includes a first wiring line provided on the display region side and formed of the same material and in the same layer as the second metal layer, a second wiring line provided on the bending portion side and formed of the same material and in the same layer as the second metal layer, and a third wiring line provided between the first wiring line and the second wiring line, formed of the same material and in the same layer as the first metal layer, and electrically connected to each of the first wiring line and the second wiring line via a first contact hole and a second contact hole formed in the inorganic insulating film.

### Advantageous Effects of Disclosure

According to the disclosure, it is possible to suppress infiltration of moisture into a display region.

### BRIEF DESCRIPTION OF DRAWINGS

FIG. 1 is a plan view illustrating a schematic configuration of an organic EL display device according to a first embodiment of the disclosure.

FIG. 2 is a plan view of a display region of the organic EL display device according to the first embodiment of the disclosure.

FIG. 3 is a cross-sectional view of the organic EL display device taken along a line III-III in FIG. 1.

FIG. 4 is an equivalent circuit diagram of a thin film transistor layer constituting the organic EL display device according to the first embodiment of the disclosure.

FIG. 5 is a cross-sectional view illustrating an organic EL layer constituting the organic EL display device according to the first embodiment of the disclosure.

FIG. 6 is a cross-sectional view of a frame region of the organic EL display device taken along a line VI-VI in FIG. 1.

FIG. 7 is a cross-sectional view of a frame region of the organic EL display device taken along a line VII-VII in FIG. 1.

FIG. 8 is a cross-sectional view of a bending portion of the organic EL display device taken along a line VIII-VIII in FIG. 1.

FIG. 9 is a cross-sectional view of a frame region of an organic EL display device according to a second embodiment of the disclosure, and is a diagram corresponding to FIG. 7.

### DESCRIPTION OF EMBODIMENTS

Embodiments of the disclosure will be described below in detail with reference to the drawings. Note that the disclosure is not limited to the embodiments to be described below.

### First Embodiment

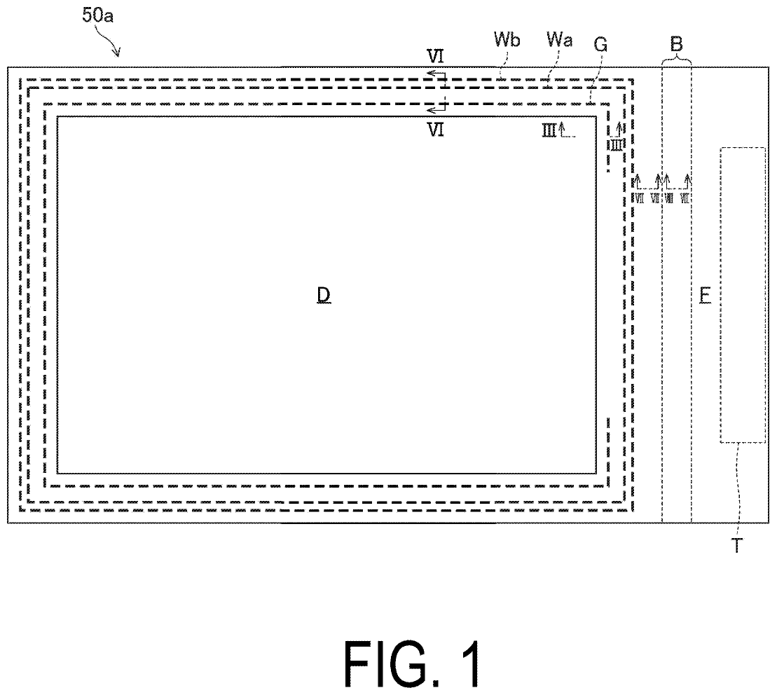

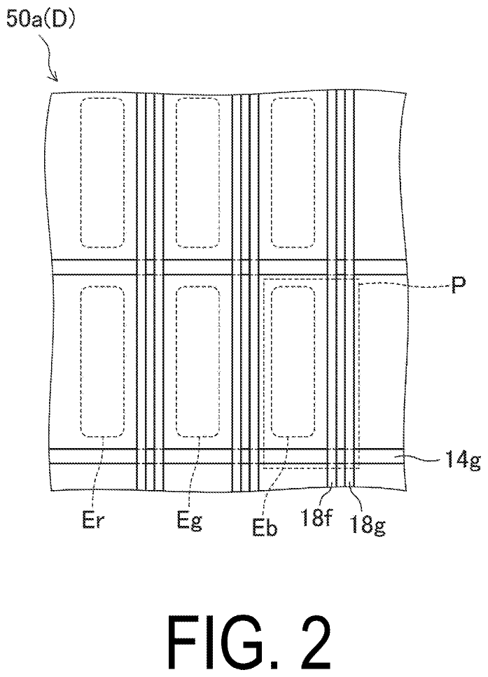

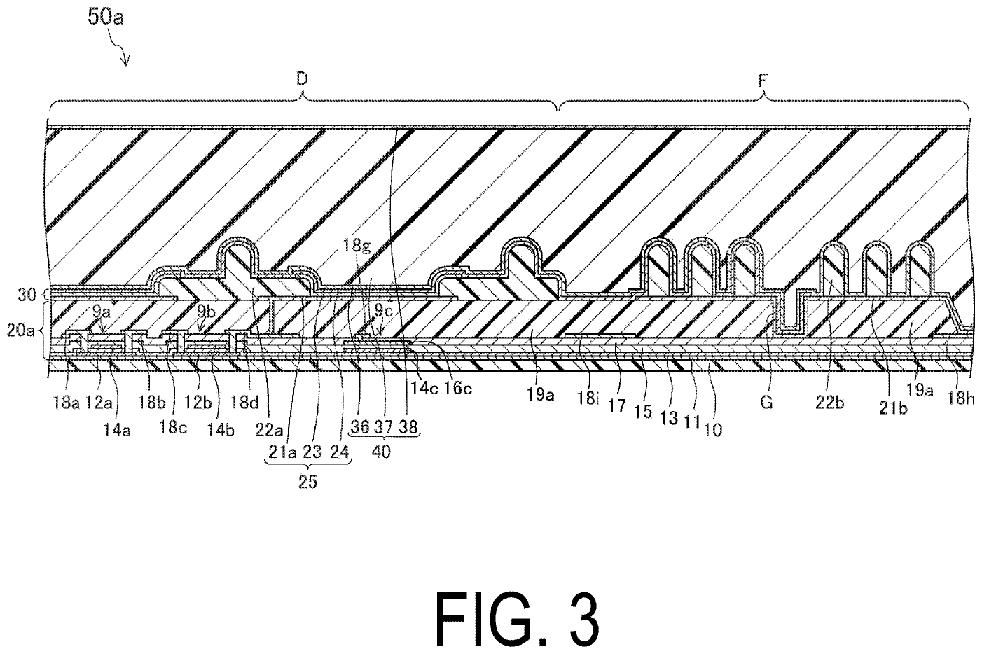

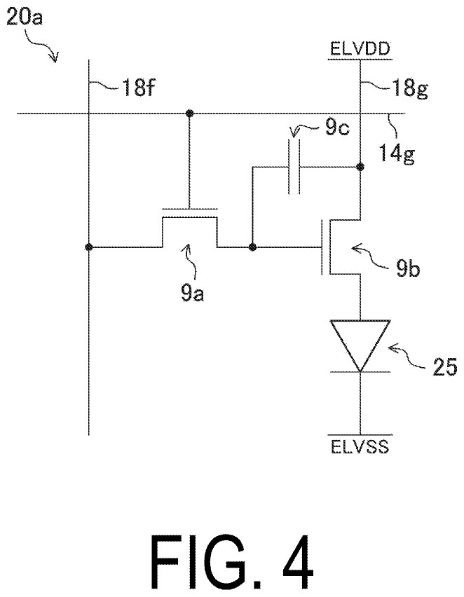

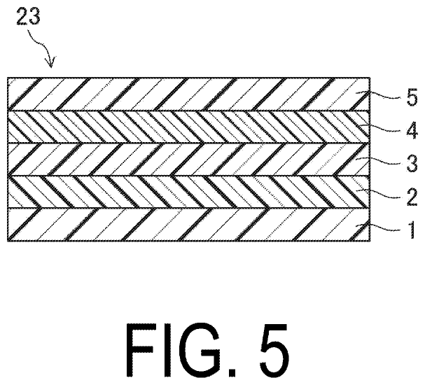

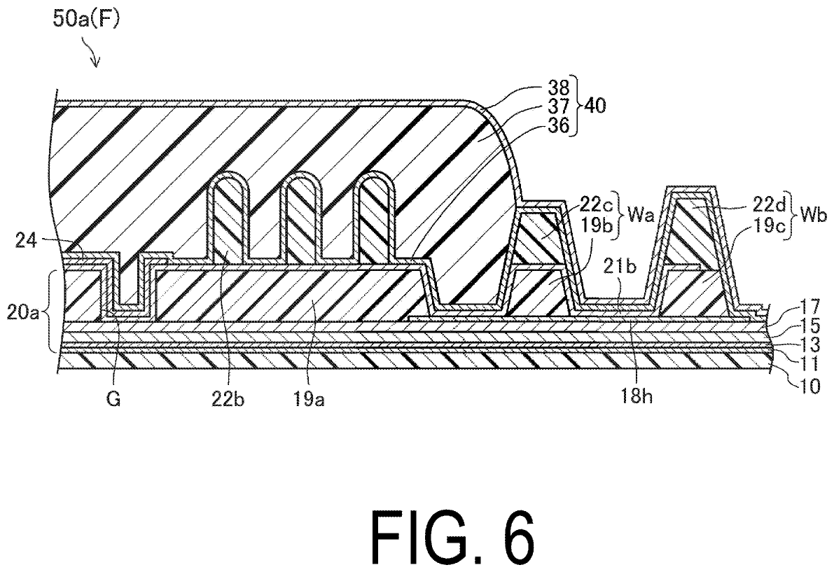

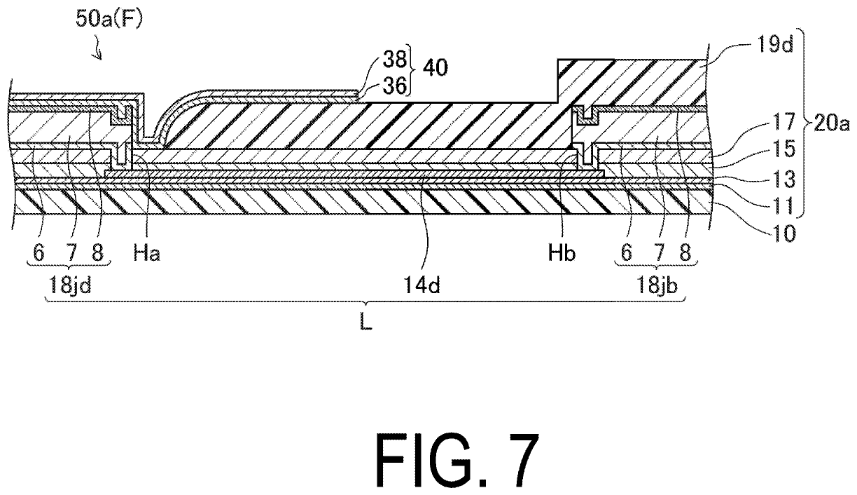

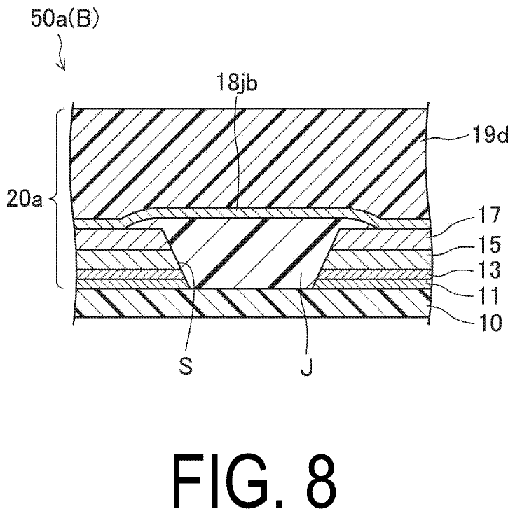

FIGS. 1 to 8 illustrate a first embodiment of a display device according to the disclosure. Note that, in each of the following embodiments, an organic EL display device including an organic EL element layer is exemplified as a display device including a light-emitting element layer. Here, FIG. 1 is a plan view illustrating a schematic configuration of an organic EL display device 50a according to the present embodiment. Further, FIG. 2 is a plan view of a display region D of the organic EL display device 50a. FIG. 3 is a cross-sectional view of the organic EL display device 50a taken along a line III-III in FIG. 1. In addition, FIG. 4 is an equivalent circuit diagram of a thin film transistor layer 20a constituting the organic EL display device 50a. In addition, FIG. 5 is a cross-sectional view illustrating an organic EL layer 23 constituting the organic EL display device 50a. In addition, FIGS. 6 and 7 are cross-sectional views of a frame region F of the organic EL display device 50a taken along a line VI-VI and a line VII-VII, respectively, in FIG. 1. In addition, FIG. 8 is a cross-sectional view of a bending portion B of the organic EL display device 50a taken along a line VIII-VIII in FIG. 1.

As illustrated in FIG. 1, the organic EL display device 50a includes, for example, a display region D that is provided in a rectangular shape and in which an image is displayed, and the frame region F provided in a frame-like shape around the display region D. Note that, in the present embodiment, the display region D having a rectangular shape is exemplified, but the rectangular shape includes substantially rectangular shapes such as a shape whose sides are arc-shaped, a shape whose corners are arc-shaped, and a shape in which a part of a side has a notch.

As illustrated in FIG. 2, a plurality of subpixels P are arrayed in a matrix shape in the display region D. In addition, as illustrated in FIG. 2, in the display region D, for example, a subpixel P including a red light-emitting region Er for displaying a red color, a subpixel P including a green light-emitting region Eg for displaying a green color, and a subpixel P including a blue light-emitting region Eb for displaying a blue color are provided adjacent to each another. Note that one pixel is constituted by, for example, the three adjacent subpixels P including the red light-emitting region Er, the green light-emitting region Eg, and the blue light-emitting region Eb in the display region D.

A terminal portion T is provided at a right end portion of the frame region F in FIG. 1 so as to extend in one direction (the vertical direction in the drawing). Further, as illustrated in FIG. 1, in the frame region F, the bending portion B that is bendable, for example, by 180° (in a U-shape) with the vertical direction in the drawing as a bending axis is provided between the display region D and the terminal portion T so as to extend in one direction (the vertical direction in the drawing). Here, in the frame region F, in a flattening film 19a to be described below, as illustrated in FIGS. 1, 3, and 6, a trench G being substantially C-shaped in a plan view is provided extending through the flattening film 19a. Note that, as illustrated in FIG. 1, the trench G is provided being substantially C-shaped with the terminal portion T side being open in a plan view.

As illustrated in FIGS. 3, 6, 7, and 8, the organic EL display device 50a includes a resin substrate 10, a thin film transistor (hereinafter, also referred to as a TFT) layer 20a provided on the resin substrate 10, an organic EL element layer 30 provided as a light-emitting element layer on the TFT layer 20a, and a sealing film 40 provided on the organic EL element layer 30 to cover the organic EL element layer 30.

The resin substrate 10 is formed of, for example, a polyimide resin.

As illustrated in FIG. 3, the TFT layer 20a includes a base coat film 11 provided on the resin substrate 10, a plurality of first TFTs 9a, a plurality of second TFTs 9b and a plurality of capacitors 9c which are provided on the base coat film 11, and the flattening film 19a provided on the first TFTs 9a, the second TFTs 9b, and the capacitors 9c. Here, as illustrated in FIGS. 2 and 4, in the TFT layer 20a, a plurality of gate lines 14g are provided as a first metal layer so as to extend in parallel with each other in the horizontal direction in the drawings. In addition, as illustrated in FIGS. 2 and 4, in the TFT layer 20a, a plurality of source lines 18f are provided as a second metal layer so as to extend in parallel with each other in the vertical direction in the drawings. Further, as illustrated in FIGS. 2 and 4, in the TFT layer 20a, a plurality of power source lines 18g are provided as a second metal layer so as to extend in parallel with each other in the vertical direction in the drawings. Then, as illustrated in FIG. 2, the power source lines 18g are provided to be adjacent to the source lines 18f. Further, as illustrated in FIG. 4, in the TFT layer 20a, each of the subpixels P includes a first TFT 9a, a second TFT 9b, and a capacitor 9c.

The base coat film 11, and a gate insulating film 13, a first interlayer insulating film 15, and a second interlayer insulating film 17, which are to be described below, are constituted by a single-layer film or a layered film of an inorganic insulating film of, for example, silicon nitride, silicon oxide, silicon oxynitride, or the like.

As illustrated in FIG. 4, the first TFT 9a is electrically connected to the corresponding gate line 14g and source line 18f in each of the subpixels P. Additionally, as illustrated in FIG. 3, the first TFT 9a includes a semiconductor layer 12a, the gate insulating film 13, a gate electrode 14a, the first interlayer insulating film 15, the second interlayer insulating film 17, and a source electrode 18a and a drain electrode 18b, which are provided in order on the base coat film 11. Here, the semiconductor layer 12a is constituted by a polysilicon film such as one of low temperature polysilicon (LTPS) in an island shape on the base coat film 11, as illustrated in FIG. 3, and includes a channel region, a source region, and a drain region. In addition, as illustrated in FIG. 3, the gate insulating film 13 is provided to cover the semiconductor layer 12a. In addition, as illustrated in FIG. 3, the gate electrode 14a is provided as a first metal layer on the gate insulating film 13 so as to overlap the channel region of the semiconductor layer 12a. In addition, as illustrated in FIG. 3, the first interlayer insulating film 15 and the second interlayer insulating film 17 are provided in order as a first inorganic insulating film and a second inorganic insulating film, respectively, so as to cover the gate electrode 14a. In addition, as illustrated in FIG. 3, the source electrode 18a and the drain electrode 18b are provided as a second metal layer on the second interlayer insulating film 17 so as to be separated from each other. In addition, as illustrated in FIG. 3, the source electrode 18a and the drain electrode 18b are electrically connected to the source region and the drain region of the semiconductor layer 12a, respectively, via contact holes formed in a layered film including the gate insulating film 13, the first interlayer insulating film 15, and the second interlayer insulating film 17. Note that the first interlayer insulating film 15 constituting one inorganic insulating film is provided on the side of the first metal layer such as the gate electrode 14a, and the second interlayer insulating film 17 constituting the other inorganic insulating film is provided on the side of the second metal layer such as the source electrode 18a and the drain electrode 18b.

As illustrated in FIG. 4, the second TFT 9b is electrically connected to the corresponding first TFT 9a and power source line 18g in each of the subpixels P. In addition, as illustrated in FIG. 3, the second TFT 9b includes a semiconductor layer 12b, the gate insulating film 13, a gate electrode 14b, the first interlayer insulating film 15, the second interlayer insulating film 17, and the source electrode 18c and the drain electrode 18d, which are provided in order on the base coat film 11. Here, the semiconductor layer 12b is constituted by a polysilicon film such as LTPS in an island shape on the base coat film 11, as illustrated in FIG. 3, and includes a channel region, a source region, and a drain region. In addition, as illustrated in FIG. 3, the gate insulating film 13 is provided to cover the semiconductor layer 12b. In addition, as illustrated in FIG. 3, the gate electrode 14b is provided as a first metal layer on the gate insulating film 13 so as to overlap the channel region of the semiconductor layer 12b. In addition, as illustrated in FIG. 3, the first interlayer insulating film 15 and the second interlayer insulating film 17 are provided in order so as to cover the gate electrode 14b. In addition, as illustrated in FIG. 3, the source electrode 18c and the drain electrode 18d are provided as a second metal layer on the second interlayer insulating film 17 so as to be separated from each other. In addition, as illustrated in FIG. 3, the source electrode 18c and the drain electrode 18d are electrically connected to the source region and the drain region of the semiconductor layer 12b, respectively, via contact holes formed in a layered film including the gate insulating film 13, the first interlayer insulating film 15, and the second interlayer insulating film 17.

Note that, in the present embodiment, the first TFT 9a and the second TFT 9b are exemplified as being of a top-gate type TFT, but the first TFT 9a and the second TFT 9b may be a bottom-gate type TFT.

The capacitor 9c is electrically connected to the corresponding first TFT 9a and power source line 18g in each of the subpixels P, as illustrated in FIG. 4. Here, as illustrated in FIG. 3, the capacitor 9c includes a lower conductive layer 14c provided as a first metal layer, the first interlayer insulating film 15 provided to cover the lower conductive layer 14c, and an upper conductive layer 16c provided as a third metal layer on the first interlayer insulating film 15 so as to overlap the lower conductive layer 14c. Note that, as illustrated in FIG. 3, the upper conductive layer 16c is electrically connected to the power source line 18g via contact holes formed in the second interlayer insulating film 17. Further, as illustrated in FIG. 3, the upper conductive layer 16c is provided between the first interlayer insulating film 15 and the second interlayer insulating film 17.

The flattening film 19a has a flat surface in the display region D, and is formed of, for example, an organic resin material such as a polyimide resin or a polysiloxane-based spin on glass (SOG) material.

As illustrated in FIG. 3, the organic EL element layer 30 includes a plurality of organic EL elements 25, provided as a plurality of light-emitting elements arrayed in a matrix shape, which correspond to the plurality of subpixels P, and an edge cover 22a provided in a lattice shape in common to all of the subpixels P so as to cover peripheral edge portions of first electrodes 21a, which will be described later, of the organic EL elements 25.

As illustrated in FIG. 3, the organic EL element 25 includes, in each of the subpixels P, the first electrode 21a provided on the flattening film 19a of the TFT layer 20a, an organic EL layer 23 provided on the first electrode 21a, and a second electrode 24 provided on the organic EL layer 23.

As illustrated in FIG. 3, the first electrode 21a is electrically connected to the drain electrode 18d of the second TFT 9b of each subpixel P via a contact hole formed in the flattening film 19a. In addition, the first electrode 21a has a function of injecting holes (positive holes) into the organic EL layer 23. In addition, it is preferable that the first electrode 21a be formed of a material having a high work function to improve the efficiency of hole injection into the organic EL layer 23. Here, examples of the material constituting the first electrode 21a include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). In addition, examples of the material constituting the first electrode 21a may include alloys such as astatine (At)/astatine oxide (AtO₂). Furthermore, examples of the material constituting the first electrode 21a may include conductive oxides such as tin oxide (SnO), zinc oxide (ZnO), indium tin oxide (ITO), and indium zinc oxide (IZO). In addition, the first electrode 21a may be formed by layering a plurality of layers formed of any of the materials described above. Note that examples of compound materials having a high work function include indium tin oxide (ITO), indium zinc oxide (IZO), and the like.

As illustrated in FIG. 5, the organic EL layer 23 includes a hole injection layer 1, a hole transport layer 2, a light-emitting layer 3, an electron transport layer 4, and an electron injection layer 5, which are provided in order on the first electrode 21a.

The hole injection layer 1 is also referred to as an anode electrode buffer layer, and has a function of reducing an energy level difference between the first electrode 21a and the organic EL layer 23 to thereby improve the efficiency of hole injection into the organic EL layer 23 from the first electrode 21a. Here, examples of the material constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function of improving the efficiency of hole transport from the first electrode 21a to the organic EL layer 23. Here, examples of the material constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons are injected from the first electrode 21a and the second electrode 24, respectively, and the holes and the electrons recombine, when a voltage is applied via the first electrode 21a and the second electrode 24. Here, the light-emitting layer 3 is formed of a material having high luminous efficiency. Moreover, examples of the material constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of efficiently moving electrons to the light-emitting layer 3. Here, examples of the material constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 has a function of reducing an energy level difference between the second electrode 24 and the organic EL layer 23 to thereby improve the efficiency of electron injection into the organic EL layer 23 from the second electrode 24, and the electron injection layer 5 can lower the drive voltage of the organic EL element 25 by this function. Note that the electron injection layer 5 is also referred to as a cathode electrode buffer layer. Here, examples of the material constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As illustrated in FIG. 3, the second electrode 24 is provided to cover the organic EL layers 23 and the edge cover 22a. In addition, the second electrode 24 has a function of injecting electrons into the organic EL layer 23. In addition, it is more preferable that the second electrode 24 be formed of a material having a low work function to improve the efficiency of electron injection into the organic EL layer 23. Here, examples of the material constituting the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The second electrode 24 may also be formed of an alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al), for example. In addition, the second electrode 24 may be formed of conductive oxide, for example, tin oxide (SnO), zinc oxide (ZnO), indium tin oxide (ITO), indium zinc oxide (IZO), or the like. In addition, the second electrode 24 may be formed by layering a plurality of layers formed of any of the materials described above. Note that examples of the material having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The edge cover 22a is formed of, for example, an organic resin material such as a polyimide resin or an acrylic resin, or a polysiloxane-based SOG material. Here, as illustrated in FIG. 3, a portion of the surface of the edge cover 22a protrudes upward in the drawing to serve as a pixel photo spacer provided in an island shape.

As illustrated in FIGS. 3 and 6, the sealing film 40 includes a first inorganic sealing film 36 provided to cover the second electrode 24, an organic sealing film 37 provided on the first inorganic sealing film 36, and a second inorganic sealing film 38 provided to cover the organic sealing film 37, and has a function of protecting the organic EL layer 23 from moisture, oxygen, and the like. Here, the first inorganic sealing film 36 and the second inorganic sealing film 38 are formed of an inorganic material such as silicon oxide (SiO₂), aluminum oxide (Al₂O₃), silicon nitride (SiNx (where x is a positive number)) such as trisilicon tetranitride (Si₃N₄), or silicon carbonitride (SiCN). In addition, the organic sealing film 37 is formed of an organic material such as an acrylic resin, a polyurea resin, a parylene resin, a polyimide resin, or a polyamide resin.

In addition, as illustrated in FIG. 1, the organic EL display device 50a includes, in the frame region F, a first dam wall Wa provided in a frame-like shape so as to surround the display region D and overlap a peripheral edge portion of the organic sealing film 37, and a second dam wall Wb provided in a frame-like shape so as to surround the first dam wall Wa.

As illustrated in FIG. 6, the first dam wall Wa includes a lower layer resin layer 19b formed of the same material and in the same layer as the flattening film 19a, and an upper layer resin layer 22c that is provided on the lower layer resin layer 19b via a conductive layer 21b and is formed of the same material and in the same layer as the edge cover 22a. Here, as illustrated in FIG. 6, the conductive layer 21b is provided being substantially C-shaped in such a manner as to overlap the trench G, the first dam wall Wa, and the second dam wall Wb in the frame region F. Note that the conductive layer 21b is formed of the same material and in the same layer as the first electrode 21a.

As illustrated in FIG. 6, the second dam wall Wb includes a lower layer resin layer 19c formed of the same material and in the same layer as the flattening film 19a, and an upper layer resin layer 22d that is provided on the lower layer resin layer 19c via the conductive layer 21b and is formed of the same material and in the same layer as the edge cover 22a.

In addition, as illustrated in FIGS. 3 and 6, the organic EL display device 50a includes a first frame wiring line 18h provided as a second metal layer being substantially C-shaped outside of the trench G in such a manner as to surround the display region D and overlap the first dam wall Wa and the second dam wall Wb in the frame region F. Here, the first frame wiring line 18h is configured such that a low power supply voltage (ELVSS) is input thereto in the terminal portion T. Further, as illustrated in FIG. 6, the first frame wiring line 18h is electrically connected to the second electrode 24 via the conductive layer 21b.

In addition, as illustrated in FIG. 3, the organic EL display device 50a includes a second frame wiring line 18i provided as a second metal layer being substantially C-shaped on the inner side of the trench G in the frame region F. Here, the second frame wiring line 18i is configured such that a high power supply voltage (ELVDD) is input thereto in the terminal portion T. In addition, the second frame wiring line 18i is electrically connected, on the display region D side, to the plurality of power source lines 18g disposed in the display region D.

In addition, as illustrated in FIG. 7, the organic EL display device 50a includes a plurality of lead wiring lines L provided between the display region D and the bending portion B in the frame region F so as to extend in parallel with each other in a direction orthogonal to the extending direction of the bending portion B.

As illustrated in FIG. 7, the lead wiring line L includes a first wiring line 18jd provided on the display region D side (the left side in the drawing), a second wiring line 18jb provided on the bending portion B side (the right side in the drawing), and a third wiring line 14d provided between the first wiring line 18jd and the second wiring line 18jb.

The first wiring line 18jd and the second wiring line 18jb are formed of the same material and in the same layer as the second metal layer such as the source electrode 18a and the drain electrode 18b, and are constituted by a titanium-based metal film 6, an aluminum-based metal film 7, and a titanium-based metal film 8 layered in order on the second interlayer insulating film 17 as illustrated in FIG. 7. Here, the titanium-based metal films 6 and 8 are constituted by, for example, a titanium film or a titanium alloy film, and the aluminum-based metal film 7 is constituted by, for example, an aluminum film or an aluminum alloy film. In addition, the first wiring line 18jd and the second wiring line 18jb may be formed in an eave shape in which both end portions of the titanium-based metal film 6 and the titanium-based metal film 8 protrude outward from both end portions of the aluminum-based metal film 7 in a cross-section orthogonal to the extending direction thereof. Note that, although the first wiring line 18jd and the second wiring line 18jb having a three-layer structure in which the titanium-based metal film 6, the aluminum-based metal film 7, and the titanium-based metal film 8 are layered in order have been exemplified in the present embodiment, the first wiring line 18jd and the second wiring line 18jb may have a two-layer structure in which, for example, an aluminum-based metal film such as an aluminum film or an aluminum-alloy film and a molybdenum-based metal film such as a molybdenum film or a molybdenum-alloy film are layered in order on the second interlayer insulating film 17.

As illustrated in FIG. 7, the first inorganic sealing film 36 and the second inorganic sealing film 38 constituting the sealing film 40 are layered in order on the first wiring line 18jd so as to cover the first wiring line 18jd.

As illustrated in FIG. 7, a wiring line covering layer 19d formed of the same material and in the same layer as the flattening film 19a is provided on the second wiring line 18jb so as to cover the second wiring line 18jb. Here, as illustrated in FIG. 7, the wiring line covering layer 19d extends to the bending portion B side (the right side in the drawing) of the second interlayer insulating film 17 disposed on the third wiring line 14d. Further, as illustrated in FIG. 7, the first inorganic sealing film 36 and the second inorganic sealing film 38 constituting the sealing film 40 are layered in order on the extended portion of the wiring line covering layer 19d so as to cover the extended portion on the display region D side (the left side in the drawing). Here, as illustrated in FIG. 7, the terminal end of the extended portion of the wiring line covering layer 19d on the display region D side (the left side in the drawing) is disposed closer to the bending portion B side (the right side in the drawing) than the terminal end of the first wiring line 18jd including a first contact hole Ha on the bending portion B side (the right side in the drawing). That is, as illustrated in FIG. 7, the terminal end of the extended portion of the wiring line covering layer 19d on the display region D side (the left side in the drawing) is provided being separated from the terminal end of the first wiring line 18jd including the first contact hole Ha on the bending portion B side (the right side in the drawing). The first inorganic sealing film 36 and the second inorganic sealing film 38 are layered in order on the second interlayer insulating film 17 of the separated portion.

The third wiring line 14d is formed of the same material and in the same layer as the first metal layer such as the gate electrode 14a, and is electrically connected to each of the first wiring line 18jd and the second wiring line 18jb via the first contact hole Ha and a second contact hole Hb formed in the first interlayer insulating film 15 and the second interlayer insulating film 17, respectively, as illustrated in FIG. 7.

In addition, as illustrated in FIG. 8, the organic EL display device 50a includes, in the bending portion B, a resin filler film J provided to fill in a slit S formed in the base coat film 11, the gate insulating film 13, the first interlayer insulating film 15, and the second interlayer insulating film 17, the second wiring line 18jb (of each lead wiring line L) provided on the resin filler film J and the second interlayer insulating film 17, and the wiring line covering layer 19d provided to cover each second wiring line 18jb. Here, as illustrated in FIG. 8, the slit S is provided in a groove shape that extends in the extending direction of the bending portion B so as to extend through the base coat film 11, the gate insulating film 13, the first interlayer insulating film 15, and the second interlayer insulating film 17, thereby exposing the surface of the resin substrate 10. Further, the resin filler film J is formed of, for example, an organic resin material such as a polyimide resin.

In addition, as illustrated in FIGS. 3 and 6, the organic EL display device 50a includes a plurality of peripheral photo spacers 22b provided in island shapes on the flattening film 19a in the frame region F so as to protrude upward in the drawings. Here, the peripheral photo spacers 22b are formed of the same material and in the same layer as the edge cover 22a.

In the organic EL display device 50a described above, in each of the subpixels P, a gate signal is input to the first TFT 9a via the gate line 14g to turn on the first TFT 9a, a data signal is written in the gate electrode 14b of the second TFT 9b and the capacitor 9c via the source line 18f, and a current from the power source lines 18g corresponding to a gate voltage of the second TFT 9b is supplied to the organic EL layer 23, whereby the light-emitting layer 3 of the organic EL layer 23 emits light to display an image. Note that, in the organic EL display device 50a, even when the first TFT 9a is turned off, the gate voltage of the second TFT 9b is held by the capacitor 9c. Thus, the light emission by the light-emitting layer 3 is maintained until a gate signal of the next frame is input.

Next, a method of manufacturing the organic EL display device 50a according to the present embodiment will be described. Here, the method of manufacturing the organic EL display device 50a according to the present embodiment includes a TFT layer forming step, an organic EL element layer forming step, and a sealing film forming step.

### TFT Layer Forming Step

First, for example, an inorganic insulating film (having a thickness of approximately 1000 nm) such as a silicon oxide film is formed on the resin substrate 10 formed on a glass substrate, for example, by a plasma chemical vapor deposition (CVD) method to form the base coat film 11.

Subsequently, for example, an amorphous silicon film (having a thickness of approximately 50 nm) is formed on the surface of substrate on which the base coat film 11 is formed, by a plasma CVD method, the amorphous silicon film is crystallized by laser annealing or the like to form a semiconductor film of a polysilicon film, and then, the semiconductor film is patterned to form the semiconductor layers 12a and 12b.

Thereafter, an inorganic insulating film (approximately 100 nm) such as a silicon oxide film is formed on the entire surface of the substrate on which the semiconductor layers 12a and 12b are formed, for example, by a plasma CVD method to form the gate insulating film 13.

Further, an aluminum film (having a thickness of approximately 350 nm), a molybdenum nitride film (having a thickness of approximately 50 nm), and the like are formed in order on the surface of the substrate on which the gate insulating film 13 is formed, for example, by a sputtering method, and then a metal layered film thereof is patterned to form the first metal layer such as the gate line 14g, the gate electrodes 14a and 14b, the lower conductive layer 14c, and the third wiring line 14d.

Subsequently, by doping impurity ions using the gate electrodes 14a and 14b as masks, a source region and a drain region are formed in the semiconductor layer 12a (12b).

Thereafter, an inorganic insulating film (having a thickness of approximately 100 nm) such as a silicon oxide film is formed, for example, by a plasma CVD method on the surface of the substrate on which the source region and the drain region are formed in the semiconductor layer 12a (12b) to form the first interlayer insulating film 15.

Subsequently, an aluminum film (having a thickness of approximately 350 nm), a molybdenum nitride film (having a thickness of approximately 50 nm), and the like are formed in order on the surface of the substrate on which the first interlayer insulating film 15 is formed, for example, by a sputtering method, and then, a metal layered film thereof is patterned to form a third metal layer such as the upper conductive layer 16c.

Further, an inorganic insulating film (having a thickness of approximately 500 nm) such as a silicon oxide film is formed on the surface of the substrate on which the third metal layer is formed, for example, by a plasma CVD method to form the second interlayer insulating film 17.

Thereafter, contact holes such as the first contact hole Ha and the second contact hole Hb are formed by appropriately patterning the gate insulating film 13, the first interlayer insulating film 15, and the second interlayer insulating film 17, and then the base coat film 11 is partially etched to form the slit S.

Subsequently, a photosensitive polyimide resin is applied to the surface of the substrate in which the slit S is formed, for example, by a spin coating method or a slit coating method, and then the coated film is subjected to prebaking, exposure, development, and postbaking to form the resin filler film J so as to fill in the slit S of the bending portion B.

Further, a titanium film (having a thickness of approximately 30 nm), an aluminum film (having a thickness of approximately 300 nm), a titanium film (having a thickness of approximately 50 nm), and the like are formed in order on the surface of the substrate on which the resin filler film J is formed, for example, by a sputtering method, and then a metal layered film thereof is patterned to form a second metal layer such as the source electrodes 18a and 18c, the drain electrodes 18b and 18d, the source line 18f, the power source line 18g, the first frame wiring line 18h, the second frame wiring line 18i, the first wiring line 18jd, and the second wiring line 18jb.

Finally, a photosensitive polyimide resin (having a thickness of approximately 2 μm) is applied to the surface of the substrate on which the second metal layer is formed, for example, by a spin coating method or a slit coating method, and then the coated film is subjected to prebaking, exposure, development, and postbaking to form the flattening film 19a, the wiring line covering layer 19d, and the like.

In this manner, the TFT layer 20a can be formed.

### Organic EL Element Layer Forming Step

The first electrode 21a, the edge cover 22a, the organic EL layer 23 (the hole injection layer 1, the hole transport layer 2, the light-emitting layer 3, the electron transport layer 4, and the electron injection layer 5), and the second electrode 24 are formed on the flattening film 19a of the TFT layer 20a, which is formed in the TFT layer forming step, by using a known method, thereby forming the organic EL element 25 and forming the organic EL element layer 30.

### Sealing Film Forming Step

First, an inorganic insulating film such as a silicon nitride film, a silicon oxide film, or a silicon oxynitride film is formed on the surface of the substrate on which the organic EL element layer 30, which is formed in the organic EL element layer forming step described above, is formed, for example, by a plasma CVD method using a mask, thereby forming the first inorganic sealing film 36.

Subsequently, a film formed of an organic resin material such as an acrylic resin is formed on the surface of the substrate on which the first inorganic sealing film 36 is formed, for example, by an ink-jet method, thereby forming the organic sealing film 37.

Further, an inorganic insulating film such as a silicon nitride film, a silicon oxide film, or a silicon oxynitride film is formed on the substrate on which the organic sealing film 37 is formed by a plasma CVD method using a mask to form the second inorganic sealing film 38, thereby forming the sealing film 40.

Finally, after a protective sheet (not illustrated) is bonded to the surface of the substrate on which the sealing film 40 is formed, a laser beam is emitted thereto from the glass substrate side of the resin substrate 10 to peel off the glass substrate from a lower surface of the resin substrate 10, and then, a protective sheet (not illustrated) is bonded to the lower surface of the resin substrate 10 from which the glass substrate has been peeled off.

In this manner, the organic EL display device 50a of the present embodiment can be manufactured.

As described above, according to the organic EL display device 50a of the present embodiment, the plurality of lead wiring lines L are provided between the display region D and the bending portion B in the frame region F so as to extend in parallel with each other in a direction orthogonal to the extending direction of the bending portion B. Here, each lead wiring line L includes the first wiring line 18jd formed on the display region D side and formed of the same material and in the same layer as the second metal layer such as the source line 18f, the second wiring line 18jb formed on the bending portion B side and formed of the same material and in the same layer as the second metal layer such as the source line 18f, and the third wiring line 14d provided between the first wiring line 18jd and the second wiring line 18jb, formed of the same material and in the same layer as the first metal layer such as the gate line 14g, and electrically connected to each of the first wiring line 18jd and the second wiring line 18jb via the first contact hole Ha and the second contact hole Hb formed in the layered film of the first interlayer insulating film 15 and the second interlayer insulating film 17. The terminal end on the display region D side of the extended portion of the wiring line covering layer 19d disposed in the bending portion B of the frame region F is provided being separated from the terminal end on the bending portion B side of the first wiring line 18jd. For this reason, even when moisture contained in the wiring line covering layer 19d disposed in the bending portion B of the frame region F moves to the display region D side along the surface of the second wiring line 18jb, the first wiring line 18jd is not directly connected to the second wiring line 18jb, and thus the moisture contained in the wiring line covering layer 19d is blocked by the first inorganic sealing film 36 and the second inorganic sealing film 38 covering the display region D side of the wiring line covering layer 19d and hardly moves to the first wiring line 18jd. Thereby, the movement of the moisture contained in the wiring line covering layer 19d of the bending portion B of the frame region F to the display region D side along the lead wiring lines L is suppressed, and thus it is possible to suppress the moisture from infiltrating into the display region D. Further, since the infiltration of the moisture into the display region D is suppressed, deterioration of the organic EL layer 23 constituting the organic EL element 25 of each subpixel P due to moisture is suppressed, and thus it is possible to suppress the occurrence of a display defect in the organic EL display device 50a.

### Second Embodiment

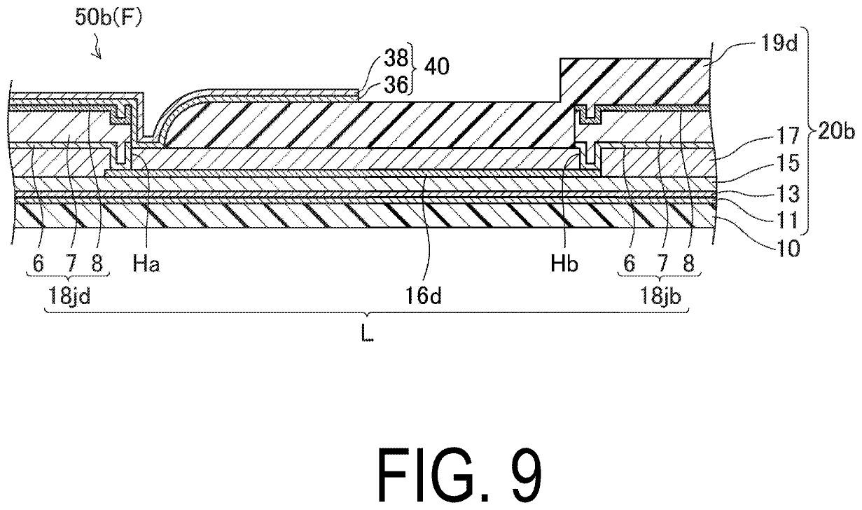

FIG. 9 illustrates a display device according to a second embodiment of the disclosure. Here, FIG. 9 is a cross-sectional view of a frame region F of an organic EL display device 50b according to the present embodiment, and is a diagram corresponding to FIG. 7. Note that, in the following embodiments, the same portions as those in FIGS. 1 to 8 are denoted by the same reference numerals and signs, and a detailed description thereof will be omitted.

Although the organic EL display device 50a including the TFT layer 20a in which the third wiring line 14d is formed of the same material and provided in the same layer as the gate line 14g and the like has been exemplified in the first embodiment described above, an organic EL display device 50b including a TFT layer 20b in which a third wiring line 16d is formed of the same material and provided in the same layer as an upper conductive layer 16c and the like is exemplified in the present embodiment. Note that, in the first embodiment, the gate line 14g and the like are the first metal layer, the source line 18f and the like are a second metal layer, and the upper conductive layer 16c and the like are a third metal layer. However, in the present embodiment, an upper conductive layer 16c and the like are a first metal layer, a source line 18f and the like are a second metal layer, and a gate line 14g and the like are a third metal layer.

Similarly to the organic EL display device 50a of the first embodiment described above, the organic EL display device 50b includes a display region D provided in a rectangular shape and a frame region F provided in a frame-like shape around the display region D.

In addition, as illustrated in FIG. 9, the organic EL display device 50b includes a resin substrate 10, a TFT layer 20b provided on the resin substrate 10, an organic EL element layer 30 (see FIG. 3) provided on the TFT layer 20b, and a sealing film 40 provided on the organic EL element layer 30 so as to cover the organic EL element layer 30.

Similarly to the TFT layer 20a according to the first embodiment described above, the TFT layer 20b includes a base coat film 11 provided on the resin substrate 10, a plurality of first TFTs 9a, a plurality of second TFTs 9b, and a plurality of capacitors 9c which are provided on the base coat film 11, and a flattening film 19a provided on the first TFTs 9a, the second TFTs 9b, and the capacitors 9c. Here, in the TFT layer 20b, the plurality of gate lines 14g are provided as a third metal layer, and the plurality of source lines 18f and a plurality of power source lines 18g are provided as a second metal layer. In addition, similarly to the TFT layer 20a according to the first embodiment described above, in the TFT layer 20b, the first TFT 9a, the second TFT 9b, and the capacitor 9c are provided in each subpixel P. Further, in the TFT layer 20b, the upper conductive layer 16c constituting the capacitor 9c is provided as a first metal layer, a second interlayer insulating film is provided as an inorganic insulating film, and a first interlayer insulating film 15 is provided as another inorganic insulating film.

Further, similarly to the organic EL display device 50a of the first embodiment described above, the organic EL display device 50b includes a first dam wall Wa, a second dam wall Wb, a first frame wiring line 18h, a second frame wiring line 18i, and a plurality of peripheral photo spacers 22b in the frame region F.

As illustrated in FIG. 9, the organic EL display device 50b includes a plurality of lead wiring lines L provided between the display region D and the bending portion B in the frame region F so as to extend in parallel with each other in a direction orthogonal to the extending direction of the bending portion B. Here, as illustrated in FIG. 9, the lead wiring line L includes a first wiring line 18jd provided on the display region D side (the left side in the drawing), a second wiring line 18jb provided on the bending portion B side (the right side in the drawing), and a third wiring line 16d provided between the first wiring line 18jd and the second wiring line 18jb. Note that the third wiring line 16d is formed of the same material and in the same layer as the first metal layer such as the upper conductive layer 16c, and is electrically connected to each of the first wiring line 18jd and the second wiring line 18jb via a first contact hole Ha and a second contact hole Hb formed in the second interlayer insulating film 17, as illustrated in FIG. 9.

Similarly to the organic EL display device 50a of the first embodiment described above, the organic EL display device 50b includes, in the bending portion B, a resin filler film J provided to fill in a slit S formed in the base coat film 11, the gate insulating film 13, the first interlayer insulating film 15, and the second interlayer insulating film 17, the second wiring line 18jb provided on the resin filler film J and the second interlayer insulating film 17, and the wiring line covering layer 19d provided to cover each second wiring line 18jb.

Similarly to the organic EL display device 50a of the first embodiment described above, the organic EL display device 50b described above is flexible and is configured to display an image by causing the light-emitting layer 3 of the organic EL layer 23 to appropriately emit light via the first TFT 9a and the second TFT 9b in each of the subpixels P.

The organic EL display device 50b of the present embodiment can be manufactured by changing the pattern shapes of the first metal layer and the third metal layer in the TFT layer forming step of the method of manufacturing the organic EL display device 50a of the first embodiment.

As described above, according to the organic EL display device 50b of the present embodiment, in the frame region F, the plurality of lead wiring lines L are provided between the display region D and the bending portion B so as to extend in parallel with each other in a direction orthogonal to the extending direction of the bending portion B. Here, each lead wiring line L includes the first wiring line 18jd formed on the display region D side and formed of the same material and in the same layer as the second metal layer such as the source line 18f, the second wiring line 18jb formed on the bending portion B side and formed of the same material and in the same layer as the second metal layer such as the source line 18f, and the third wiring line 16d provided between the first wiring line 18jd and the second wiring line 18jb, formed of the same material and in the same layer as the first metal layer such as the upper conductive layer 16c, and electrically connected to each of the first wiring line 18jd and the second wiring line 18jb via the first contact hole Ha and the second contact hole Hb formed in the second interlayer insulating film 17. The terminal end on the display region D side of the extended portion of the wiring line covering layer 19d disposed in the bending portion B of the frame region F is provided being separated from the terminal end on the bending portion B side of the first wiring line 18jd. For this reason, even when moisture contained in the wiring line covering layer 19d moves to the display region D side along the surface of the second wiring line 18jb, the first wiring line 18jd is not directly connected to the second wiring line 18jb, and thus the moisture contained in the wiring line covering layer 19d is blocked by the first inorganic sealing film 36 and the second inorganic sealing film 38 covering the display region D side of the wiring line covering layer 19d and hardly moves to the first wiring line 18jd. Thereby, the movement of the moisture contained in the wiring line covering layer 19d of the bending portion B of the frame region F to the display region D side along the lead wiring lines L is suppressed, and thus it is possible to suppress the moisture from infiltrating into the display region D. Further, since the infiltration of the moisture into the display region D is suppressed, deterioration of the organic EL layer 23 constituting the organic EL element 25 of each subpixel P due to moisture is suppressed, and thus it is possible to suppress the occurrence of a display defect in the organic EL display device 50b.

### Other Embodiments

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

Although the organic EL display device including the first electrode as an anode electrode and the second electrode as a cathode electrode has been exemplified in each of the embodiments described above, the disclosure is also applicable to an organic EL display device in which the layered structure of the organic EL layer is reversed with the first electrode being a cathode electrode and the second electrode being an anode electrode.

Although the organic EL display device in which the electrode of the TFT connected to the first electrode serves as the drain electrode has been exemplified in each of the embodiments described above, the disclosure is also applicable to an organic EL display device in which the electrode of the TFT connected to the first electrode is referred to as the source electrode.

Although the organic EL display device has been exemplified as a display device in each of the embodiments described above, the disclosure can also be applied to a display device including a plurality of light-emitting elements driven by a current, for example, to a display device including quantum dot light-emitting diodes (QLEDs), which are a light-emitting element using a quantum dot-containing layer.

### INDUSTRIAL APPLICABILITY

As described above, the disclosure is useful for a flexible display device.

1. A display device comprising:
a resin substrate;
a thin film transistor layer provided on the resin substrate and in which a first metal layer, an inorganic insulating film, a second metal layer, and an organic resin film are layered in order;
a light-emitting element layer provided on the thin film transistor layer and in which a plurality of light-emitting elements are arrayed corresponding to a plurality of subpixels constituting a display region; and
a sealing film provided on the light-emitting element layer to cover the light-emitting element layer and in which a first inorganic sealing film, an organic sealing film, and a second inorganic sealing film are layered in order,
wherein a frame region is provided around the display region,
a terminal portion is provided at an end portion of the frame region,
a bending portion is provided between the display region and the terminal portion, the bending portion extending in one direction,
a plurality of lead wiring lines are provided between the display region and the bending portion in the frame region, the plurality of lead wiring lines extending in parallel with each other in a direction intersecting a direction in which the bending portion extends, and
each of the lead wiring lines includes a first wiring line provided on the display region side and formed of the same material and in the same layer as the second metal layer, a second wiring line provided on the bending portion side and formed of the same material and in the same layer as the second metal layer, and a third wiring line provided between the first wiring line and the second wiring line, formed of the same material and in the same layer as the first metal layer, and electrically connected to each of the first wiring line and the second wiring line via a first contact hole and a second contact hole formed in the inorganic insulating film.

2. The display device according to claim 1,
wherein a wiring line covering layer formed of the same material and in the same layer as the organic resin film is provided on the second wiring line to cover the second wiring line.

3. The display device according to claim 2,
wherein the wiring line covering layer extends to the bending portion side of the inorganic insulating film provided on the third wiring line.

4. The display device according to claim 3,
wherein the first inorganic sealing film and the second inorganic sealing film are layered in order on the first wiring line to cover the first wiring line.

5. The display device according to claim 4,
wherein the first inorganic sealing film and the second inorganic sealing film are layered in order on an extended portion of the wiring line covering layer to cover the extended portion on the display region side.

6. The display device according to claim 5,
wherein an end portion of the extended portion of the wiring line covering layer on the display region side is provided being separated from an end portion of the first wiring line on the bending portion side.

7. The display device according to claim 1,
wherein the inorganic insulating film includes a first inorganic insulating film provided on the first metal layer side and a second inorganic insulating film provided on the second metal layer side, and
a third metal layer is provided between the first inorganic insulating film and the second inorganic insulating film.

8. The display device according to claim 1,
wherein a third metal layer is provided on the resin substrate side of the first metal layer with another inorganic insulating film interposed between the third metal layer and the first metal layer.

9. The display device according to claim 1,
wherein the second metal layer is constituted by a titanium-based metal film, an aluminum-based metal film, and a titanium-based metal film which are layered in order on the inorganic insulating film.

10. The display device according to claim 1,
wherein the second metal layer is constituted by an aluminum-based metal film and a molybdenum-based metal film which are layered in order on the inorganic insulating film.

11. The display device according to claim 1,
wherein a slit is provided in the inorganic insulating film, the slit extending in the direction in which the bending portion extends and exposing the surface of the resin substrate in the bending portion,
a resin filler film is provided in the bending portion to fill in the slit, and
the second wiring line is provided on the resin filler film.

12. The display device according to claim 1,
wherein each of the light-emitting elements is an organic electroluminescence element.
